(19) United States
(12) Patent Application Publication
(10) Pub. No.: US 2005/0173766 A1
(43) Pub. Date: Aug. 11, 2005

(54) Semiconductor memory and manufacturing method thereof

(75) Inventors: Hee-soon Chae, Yongin-si (KR); Jo-won Lee, Suwon-si (KR); Chung-woo Kim, Seongnam-si (KR); Eun-hong Lee, Anyang-si (KR)

Correspondence Address: LEE, STERBA & MORSE, P.C., SUITE 2000, 1101 WILSON BOULEVARD, ARLINGTON, VA, 22209, US

(73) Assignee: Samsung Electronics Co., Ltd.

(21) Appl. No.: 11/029,018

(22) Filed: Jan. 5, 2005

(30) Foreign Application Priority Data
Jan. 5, 2004 (KR) 10-2004-0000359

(51) Int. Cl. H01L 29/76; H01L 21/8238

(52) U.S. Cl. 257/369; 438/199

(57) ABSTRACT

In a semiconductor memory, and a manufacturing method thereof, the semiconductor memory includes a gate stack structure formed on a semiconductor substrate, first and second impurity regions formed adjacent each side of the gate stack structure on the semiconductor substrate, the first and second impurity regions having a channel region therebetween, and a contact layer formed on the semiconductor substrate adjacent either the first or second impurity region.

### BACKGROUND OF THE INVENTION

1. Field of the Invention

The present invention relates to a semiconductor memory. More particularly, the present invention relates to a semiconductor memory having an increased operating speed and a manufacturing method thereof.

2. Description of the Related Art

Data storage capacity of semiconductor memory is determined by degree of integration, i.e., the number of memory cells per unit area. A conventional semiconductor memory includes a number of cells constituting memory circuit. For example, a conventional DRAM cell includes one transistor and one capacitor.

As a result of studies on large scale integrated (LSI) circuits having a high operating speed and low power consumption, technologies using a silicon-on-insulator (SOI) substrate have been developed for use in next generation semiconductor memory. Advantageously, an SOI substrate can be fabricated in a relatively simple way. Also, regarding isolation of unit elements, SOI substrate technology allows a short isolation distance in NMOS or CMOS, thereby resulting in higher integration of the semiconductor memory. Therefore, an SOI substrate is widely used for memory with geometries of about 100 nm and below.

FIG. 1A illustrates a structure of an SOI substrate on which a silicon-oxide-nitride-oxide-silicon (SONOS) memory is formed. A SONOS memory is one relatively recently developed memory.

Referring to FIG. 1A, a gate stack structure 16 on an SOI substrate 11 includes sequentially stacked layers of a tunneling oxide layer 12, a dielectric layer 13, a blocking oxide layer 14, and a gate electrode 15. The tunneling oxide layer 12, the dielectric layer 13, and the blocking oxide layer 14 constitute an ONO layer. The SOI substrate 11 includes sequentially stacked layers of a silicon (Si) layer 11a, an oxide layer 11b, and a Si bulk layer 11c. A doped source 17a and drain 17b, which each have a polarity opposite to the Si bulk layer 11c, are formed on a surface of the Si bulk layer 11c.

Though SOI substrates are widely used for memories having a gate stack structure of about 100 nm or below in thickness, an electric potential of the Si bulk layer 11c is not constantly maintained because the Si bulk layer 11c is floating on the oxide layer 11b. Therefore, the data write/erase speed of the SONOS memory on the SOI substrate becomes slower than that of the SONOS memory on an Si substrate. Further, when stored data is erased, the electric potential of the Si bulk layer 11c is lower than a negative electric potential of the gate electrode 15 because the gate electrode 15 and the bulk layer 11c are coupled by a capacitor, thereby slowing the data erase speed.

FIG. 1B is a graph illustrating a data write/erase speed of an SONOS memory formed on an SOI substrate. FIG. 1C is a graph illustrating a data write/erase speed of an SONOS memory formed on an Si substrate. The ONO structure of the gate stack structure 16 used for measurement to plot FIGS. 1B and 1C includes the tunneling oxide layer 12, the dielectric layer 13, and the blocking oxide layer 14 having thicknesses of 20 Å, 60 Å, and 45 Å, respectively, for the same measurement condition. As may be seen, the data write/erase speed of FIG. 1C is much slower than that of FIG. 1B. More specifically, when comparing a decrease of threshold voltage with respect to time, the SONOS memory on the Si substrate (FIG. 1C) has a larger amount of decrease than the SONOS memory on the SOI substrate 11 (FIG. 1B). The reason for this larger decrease is that additional voltage cannot be applied to the Si bulk layer 11c of the SOI substrate because the Si bulk layer 11c is floating on the oxide layer 11b.

Therefore, in a case of a Fowler-Nordheim (FN) tunneling method using a voltage difference between the gate electrode 15 and the Si bulk layer 11c, the data erase speed is reduced. Also, it is impossible to use a method of applying voltage to the Si bulk layer 11c for improving the data write speed.

Further, in a case of an SONOS memory cell array, in which a plurality of SONOS memory cells are arranged on the SOI substrate, the electric potential of the Si bulk layer 11c varies over the memory cell array and thus each memory cell has a different operating speed and the memory cell array becomes unstable. That is, though each of the memory cells is formed on the same SOI substrate, there occurs a problem in that each electric potential of the SOI substrate is not constant.

### SUMMARY OF THE INVENTION

The present invention is therefore directed to a semiconductor memory and manufacturing method thereof, which substantially overcome one or more of the problems due to the limitations and disadvantages of the related art.

It is a feature of an embodiment of the present invention to provide a semiconductor memory, and a manufacturing method thereof, in which a structure of the memory on an SOI substrate is improved to increase operating speed.

It is another feature of an embodiment of the present invention to provide a semiconductor memory, and manufacturing method thereof, which provides a reliable data write/erase operation and a fast operation speed.

It is still another feature of an embodiment of the present invention to provide a semiconductor memory, and manufacturing method thereof, which is able to provide a stable memory cell array.

At least one of the above and other features and advantages of the present invention may be realized by providing a semiconductor memory including a gate stack structure formed on a semiconductor substrate, first and second impurity regions formed adjacent each side of the gate stack structure on the semiconductor substrate, the first and second impurity regions having a channel region therebetween, and a contact layer formed on the semiconductor substrate adjacent either the first or second impurity region.

The gate stack structure may include sequentially stacked layers of a tunneling oxide layer, a dielectric layer, a blocking layer, and a gate electrode. The tunneling oxide layer and the blocking layer may be formed of at least one selected from the group consisting of SiO₂, HfON, Al₂O₃, TaO₂, TiO₂, and High-k. The dielectric layer may be formed of an Si-dot or a nitride layer. The dielectric layer may be Si₃N₄.

At least one of the above and other features and advantages of the present invention may be realized by providing a manufacturing method of a semiconductor memory including (a) forming a trench on a first portion of a semiconductor substrate and depositing an insulating material in the trench, (b) forming a gate stack structure on a second portion of the semiconductor substrate and doping a conductive impurity into the semiconductor substrate adjacent the gate stack structure to form doped regions, and (c) forming a contact layer on a third portion of the semiconductor substrate adjacent to the trench and on an opposite side of the trench as the gate stack structure.

Forming the trench on the first portion of a semiconductor substrate and depositing the insulating material in the trench may include depositing a nitride layer on the semiconductor substrate, etching the first portion of the semiconductor substrate to form the trench, and depositing the insulating layer in the trench and removing the nitride layer.

Forming the gate stack structure on the second portion of the semiconductor substrate and doping the conductive impurity into the semiconductor substrate adjacent the gate stack structure to form doped regions may include depositing layers for forming the gate stack structure on the second portion of the semiconductor substrate and etching the layers to form the gate stack structure and forming a first impurity region and a second impurity region using a doping process in which a conductive impurity is doped into the semiconductor substrate adjacent the gate stack structure. The first and second impurity regions may both have a polarity opposite to that of an upper portion of the semiconductor substrate.

Forming the first and second impurity regions may further include doping a low density impurity into the semiconductor substrate adjacent the gate stack structure, forming a sidewall spacer on each side of the gate stack structure, and doping a high density impurity into the semiconductor substrate adjacent the sidewall spacers on the gate stack structure to complete the first and the second impurity regions.

Forming the gate stack structure may include depositing sequentially an oxide, a dielectric, an oxide, and an electrode material and etching each of the deposited materials.

Forming the contact layer on the third portion of the semiconductor substrate adjacent to the trench and on an opposite side of the trench as the gate stack structure may include doping a conductive impurity into the semiconductor substrate located at one side of the trench opposite to the gate stack structure.

The contact layer may have a polarity opposite to the first and second impurity regions and may have the same polarity as an upper portion of the semiconductor substrate.

The manufacturing method may further include forming an insulating layer between the doped regions and the contact layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1A illustrates a sectional view of a conventional SONOS memory formed on an SOI substrate;

FIG. 1B is a graph of threshold voltage versus time for a conventional SONOS memory formed on an SOI substrate;

FIG. 1C is a graph of threshold voltage versus time for a conventional SONOS memory formed on an Si substrate;

FIG. 2 illustrates a sectional view of a semiconductor memory according to an embodiment of the present invention;

FIGS. 3A through 3H illustrate sectional views of stages in a manufacturing method of a semiconductor memory according to an embodiment of the present invention; and

FIGS. 4A and 4B are graphs of threshold voltage versus time for a semiconductor memory according to an embodiment of the present invention in comparison with a conventional semiconductor memory.

### DETAILED DESCRIPTION OF THE INVENTION

Korean Patent Application No. 10-2004-0000359, filed on Jan. 5, 2004, in the Korean Intellectual Property Office, and entitled: “Semiconductor Memory and Manufacturing Method Thereof,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of films, layers and regions are exaggerated for clarity of illustration. It will also be understood that when a layer is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

FIG. 2 illustrates a sectional view of a semiconductor memory according to an embodiment of the present invention. Referring to FIG. 2, a gate stack structure 26 is formed on a silicon-on-insulator (SOI) substrate 21. The gate stack structure 26 includes sequentially stacked layers of a tunneling oxide layer 22, a dielectric layer 23, a blocking oxide layer 24, and a gate electrode 25. The SOI substrate 21 includes an Si layer 21a, an oxide layer 21b, and a Si bulk layer 21c, which are formed in sequence. A first impurity region and a second impurity region, each having a polarity opposite to the Si bulk layer 21c, are formed on a surface of the Si bulk layer 21c. The first impurity region may be a source 27a and the second impurity region may be a drain 27b. During the manufacturing process, sidewalls spacers 28 are formed on each sidewall of the gate stack structure 26. An optional insulating layer 33, which is formed after a selective etching, may be formed on one portion of the Si bulk layer 21c. A contact layer 34 is formed adjacent to the insulating layer 33, and on an opposite side from the drain 27b side of the gate stack structure 26, in order to maintain an electric potential of the Si bulk layer 21c constant. Although illustrated adjacent the drain 27b, the insulating layer 33 may alternatively be formed adjacent to the source 27a and the contact layer 34 may be formed adjacent to the contact layer 34, and on an opposite side from the source 27a side of the gate stack structure 26.

The tunneling oxide 22 and the blocking oxide 24 may be made of at least one of SiO₂, HfON, Al₂O₃, TaO₂, TiO₂, and High-k. The dielectric layer 23 can be made of any type of usual dielectric material, e.g., a nitride such as Si₃N₄ or an Si-dot. In operation, a proper voltage, e.g., threshold voltage Vth, is applied to the gate stack structure 26 such that electrons passing the tunneling oxide layer 22 are trapped at the dielectric layer 23. One case in which the electrons are trapped at the dielectric layer 23 can be denoted by “1” and an opposite case can be denoted by “0”, which means data store/erase state. More specifically, though the memory of the present invention has a transistor-type structure, it can store data and thus can be called a multi-functional device, i.e., a data-storing transistor or a memory transistor.

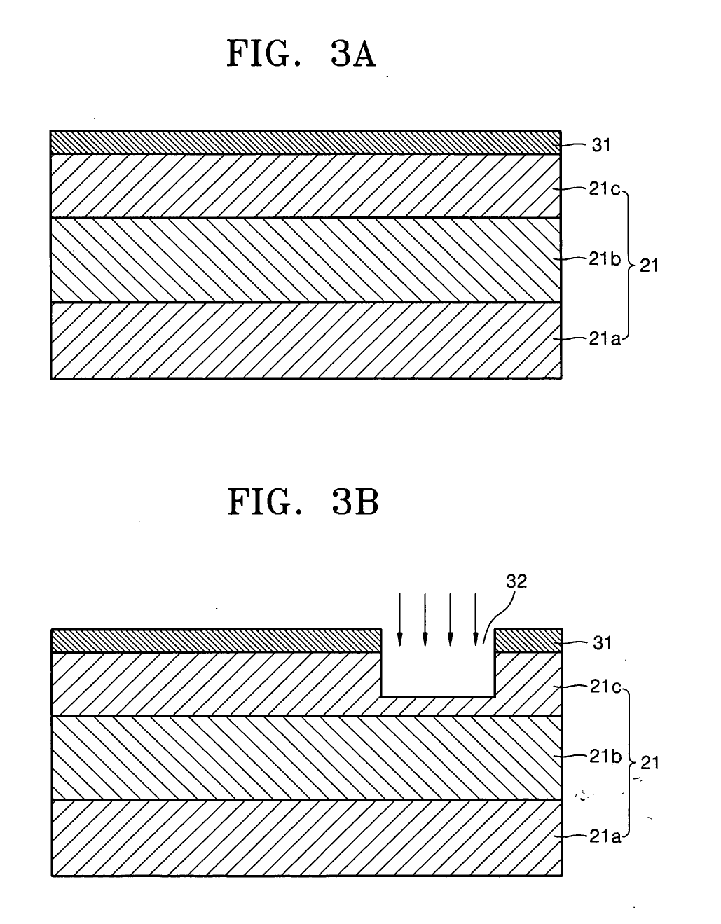

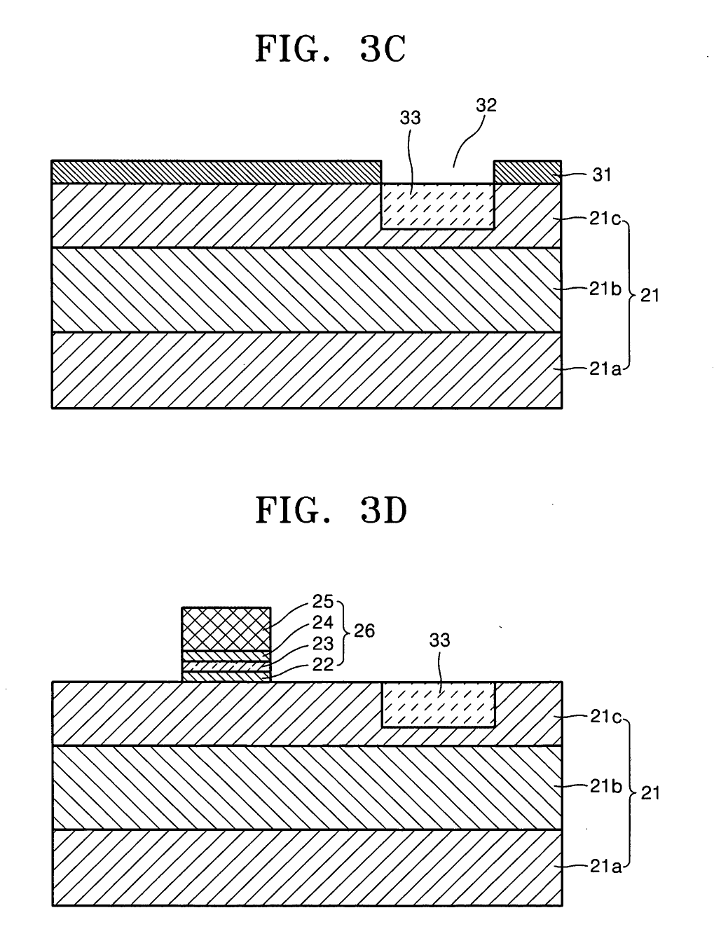

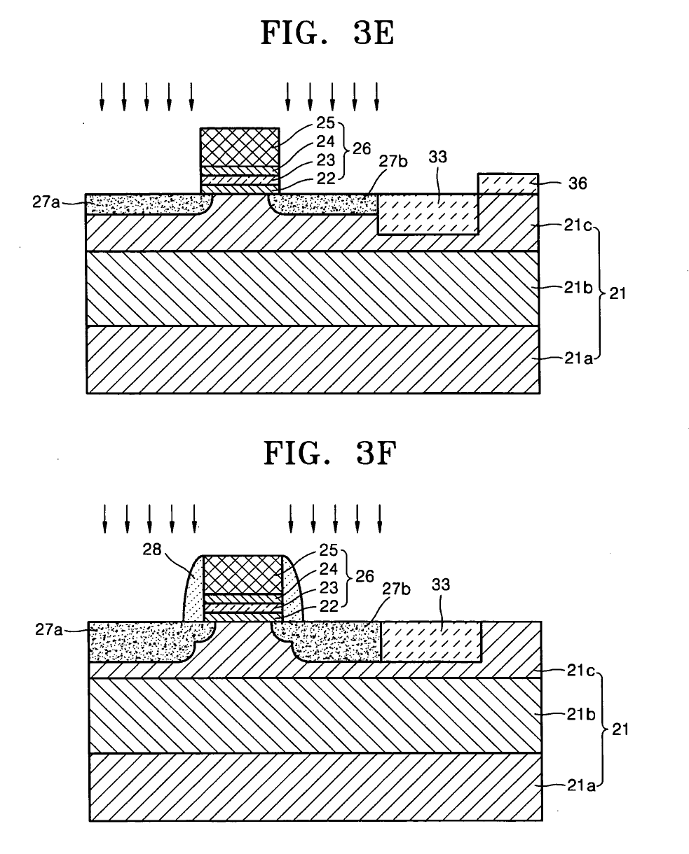

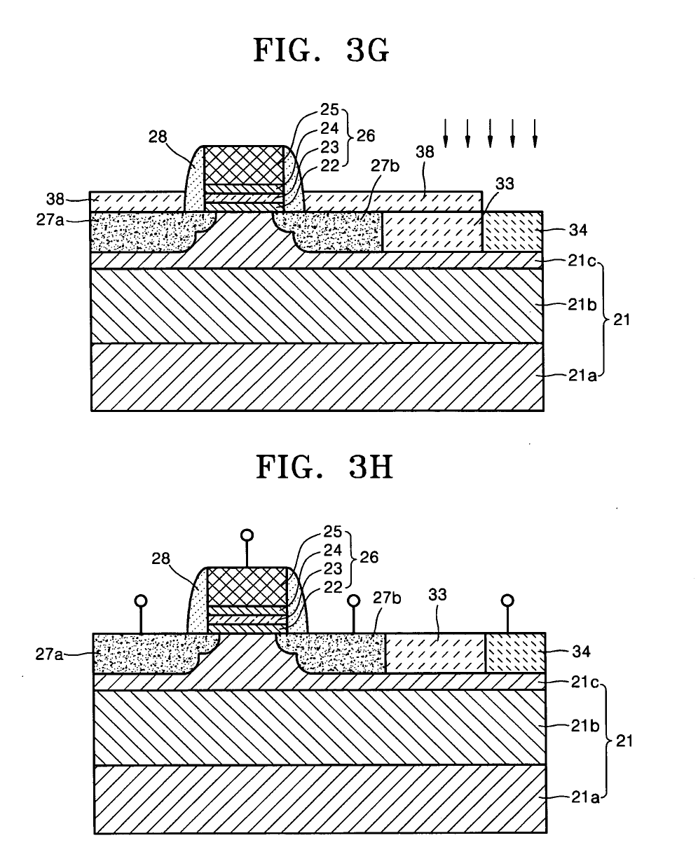

A manufacturing method of a semiconductor memory of the present invention will now be described more fully with reference to the accompanying drawings. FIGS. 3A through 3H illustrate sectional views of stages in a manufacturing method of a semiconductor memory of an embodiment of the present invention.

Referring to FIG. 3A, the SOI substrate 21 includes the Si layer 21a, the oxide layer 21b, and the Si bulk layer 21c, which are sequentially formed. The SOI substrate 21 may be a conventional SOI substrate. A nitride layer 31, such as Si₃N₄, is then deposited over the SOI substrate 21 for use in a shallow trench isolation (STI) method of forming a trench 32 (shown FIG. 3B) in the SOI substrate 21.

Referring to FIG. 3B, an etching process is performed to one portion of the Si bulk layer 21c using the STI method, thereby forming the trench 32. A depth of the trench 32 may be adjusted to avoid exposing an upper surface of the oxide layer 21b. The trench 32 may be formed to flow current within a limited portion of the Si bulk layer 21c.

Referring to FIG. 3C, an insulating material, such as an oxide material, is deposited in the trench 32 to form an insulating layer 33. The insulating material may be deposited to partially fill the trench 32.

Referring to FIG. 3D, the nitride layer 31 formed on the Si bulk layer 21c is removed and an upper surface of the Si bulk layer 21c is exposed. The tunnelling oxide layer 22, the dielectric layer 23, the blocking layer 24, and the gate electrode 25, which collectively constitute the gate stack structure 26, are sequentially formed on the SOI substrate 21. The layers 22, 23, 24 and the gate electrode 25 of the gate stack structure 26 may be made using conventional materials and methods. The tunnelling oxide layer 22 and the blocking layer 24 may be formed of at least one of SiO₂, HfON, Al₂O₃, TaO₂, TiO₂, and High-k. The dielectric layer 23 may be formed of Si₃N₄ or an Si-dot. Each side of the gate stack structure 26 is removed using an etching such that a predetermined width of the resultant gate stack structure 26 is obtained. Usually, the width of the gate stack structure is adjusted to below about 100 nm.

Referring to FIG. 3E, a low-density impurity (dopant) is doped in order to form impurity regions on the Si bulk layer 21c. The impurity regions on the Si bulk layer 21c may be located adjacent either side of the gate stack structure 26. One impurity region beside one side of the gate stack structure 26 is the source 27a and the other impurity region beside the other side of the gate stack structure 26 is the drain 27b. A doping mask 36 limits the doping to the gate stack structure region and the impurity regions.

At this time, because a width of the gate stack structure 26 is narrow, the dopant can be diffused to a channel region that is interposed below the gate stack structure 26 between the source 27a and the drain 27b, and thus, the source 27a and the drain 27b can electrically contact each other. To prevent this phenomenon, a two-step doping process is used in which the low-density dopant is first doped and then, if the phenomenon does not occur, a proper density of dopant is second doped to complete the source 27a and the drain 27b.

Referring to FIG. 3F, after the low-density dopant is doped, sidewalls spacers 28 are formed on either side of the gate stack structure 26 and the proper density of dopant is doped to the source 27a and the drain 27b regions, i.e., the second doping is performed. A type and density of the dopant is adjusted so that the source 27a and the drain 27b have a polarity opposite to that of the Si bulk layer 21c. The dopant is doped to regions of the semiconductor substrate 21 except the insulating layer 33 region.

Referring to FIG. 3G, a doping process for forming a contact layer 34 is performed to a region that is located adjacent to the insulating layer 33 on an opposite side from the gate stack structure 26. A doping mask 38 limits the doping to the above-described region. The doping process is performed with a dopant having a polarity opposite to the source 27a and drain 27b, but the same as the Si bulk layer 21c. The density of the dopant may be higher than that of the Si bulk layer 21c.

Referring to FIG. 3H, after those processes are performed, the semiconductor memory of the present invention is completed and a sectional view of the completed memory is shown in FIG. 2.

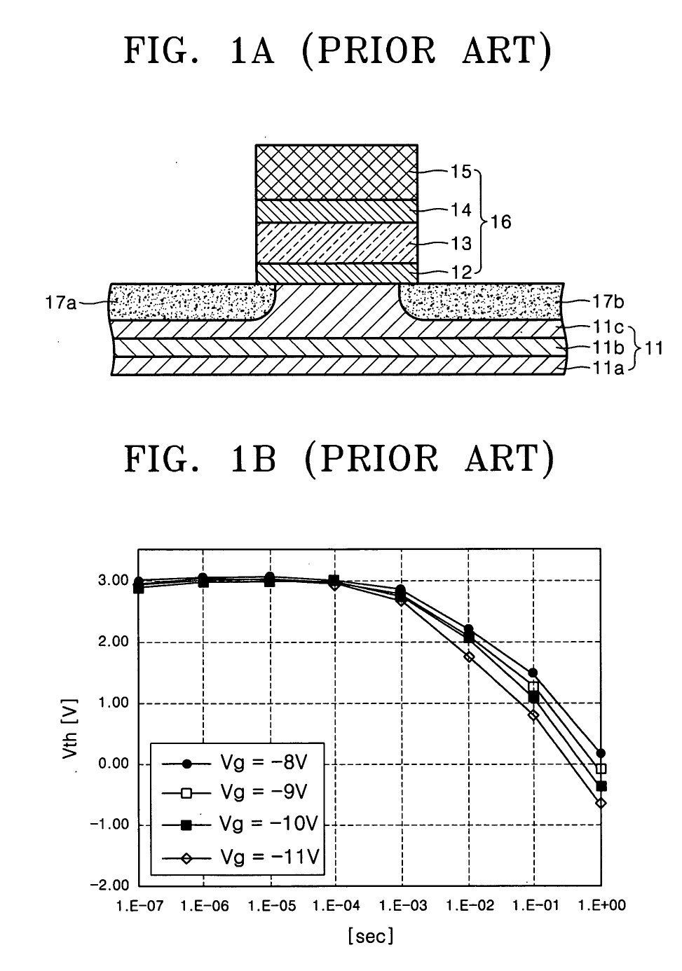

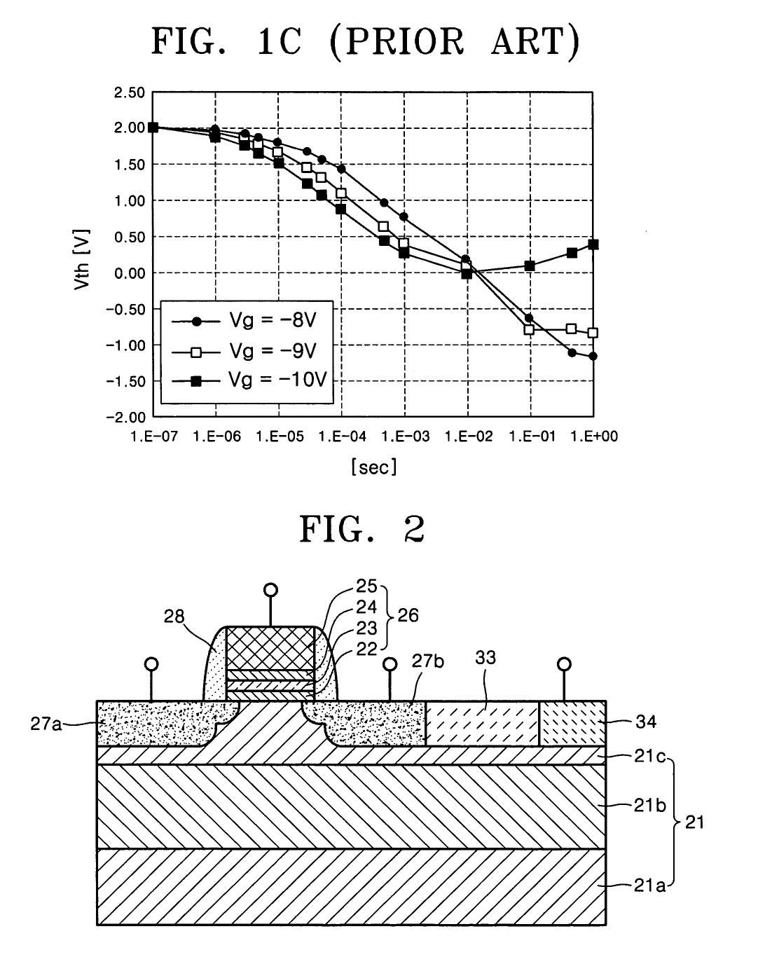

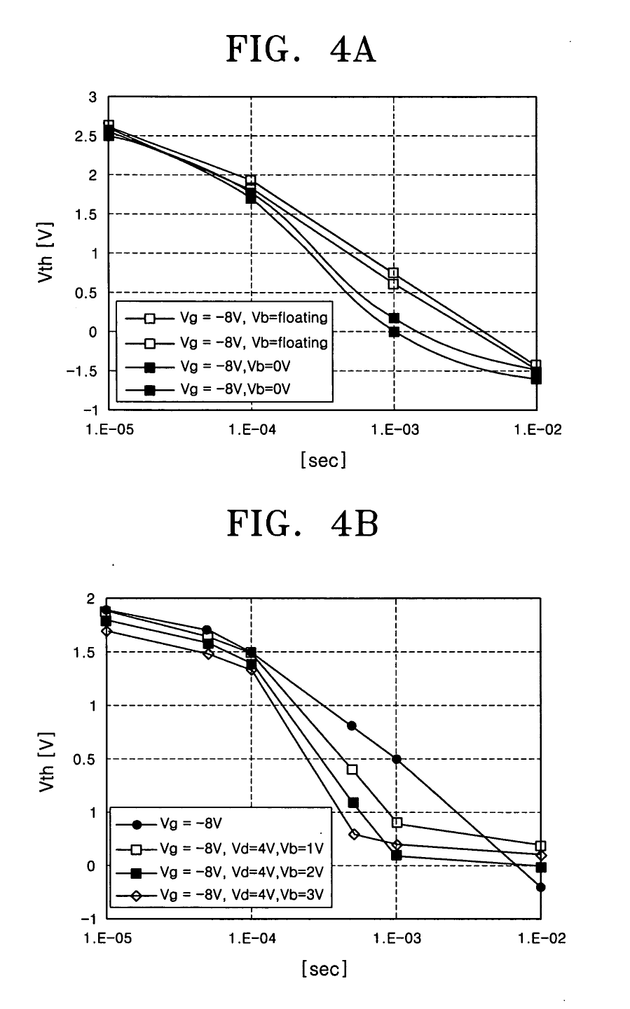

FIG. 4A is a graph of threshold voltage versus time in which a conventional semiconductor memory and a semiconductor memory according to an embodiment of the present invention can be compared. Herein, an ONO layer of each memory has a structure in which the tunnelling layer 22, the dielectric layer 23, and the blocking oxide layer 24 have thicknesses of 20 Å, 60 Å, and 45 Å, respectively. The thicknesses of these layers are the same as those layers of the memory used for plotting the graphs in FIGS. 1B and 1C.

Referring to FIG. 4A, when an electric potential of the Si bulk layer 21c is fixed equal to ground potential, i.e., Vb=0V, according to the present invention, a decrease of the threshold voltage with respect to time is higher than that of a conventional SONOS memory formed on the SOI substrate in the floating state, which means that the data erase speed of the memory of the present invention is slower that that of the conventional memory. More specifically, between the memory of the present invention and the conventional SONOS memory, both which are formed on the same type of substrate, i.e., a SOI substrate, the memory of the present invention has a faster data erase time than the conventional SONOS memory because the Si bulk layer 21c of the present invention has a fixed electric potential due to the contact layer 34 while that of a Si bulk layer 11c of the conventional SONOS memory is not fixed.

FIG. 4B is a graph of threshold voltage versus time of a semiconductor memory according to an embodiment of the present invention when the Si bulk layer 21c is applied with zero through three volts while applying fixed voltages to the gate stack structure 26, i.e., Vg=−8V, and the drain 27b, i.e., Vd=4V.

Referring to FIG. 4B, a variation, i.e., a decrease, in threshold voltage with respect to time is much higher when the Si bulk layer 21c is applied with constant voltage rather than applied with floating voltage. That is, when the Si bulk layer 21c is applied with constant voltage, the data erase speed is much higher.

Therefore, when semiconductor memory cells using the contact layer 34 are arranged in a memory cell array, the electric potential of the Si bulk layer 21c can be constantly maintained during an operation of the memory cell array, thereby improving operating speed and stability of the whole memory.

Meanwhile, not only SONOS memory but also various semiconductor memories having a transistor structure can adopt the contact layer 34. The contact layer 34 may be formed on a rear of the gate stack structure 26 as well as to a side of the source 27a or the drain 27b. In other words, because the contact layer 34 is designed to fix the electric potential of the Si bulk layer, the location of the contact layer 34 is not limited to the side of the source 27a or the drain 27b.

According to an embodiment of the present invention, the semiconductor memory is provided on one portion of a substrate with the contact layer 34, thereby obtaining a reliable data write/erase and fast operation speed. Further, applying this structure to a memory cell array, the Si bulk layer 21c of the SOI substrate 21 can be applied with constant and proper electric potential, thereby providing a stable memory cell array.

Exemplary embodiments of the present invention have been disclosed herein and, although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

1. A semiconductor memory, comprising:
a gate stack structure formed on a semiconductor substrate;
first and second impurity regions formed adjacent each side of the gate stack structure on the semiconductor substrate, the first and second impurity regions having a channel region therebetween; and
a contact layer formed on the semiconductor substrate adjacent either the first or second impurity region.

2. The semiconductor memory as claimed in claim 1, wherein the gate stack structure comprises sequentially stacked layers of a tunneling oxide layer, a dielectric layer, a blocking layer, and a gate electrode.

3. The semiconductor memory as claimed in claim 1, wherein the semiconductor substrate comprises sequentially stacked layers of a silicon (Si) layer, an oxide layer, and an Si bulk layer.

4. The semiconductor memory as claimed in claim 1, further comprising an insulating layer formed either between the first impurity layer and the contact layer or between the second impurity region and the contact layer.

5. The semiconductor memory as claimed in claim 2, wherein the tunneling oxide layer and the blocking layer are formed of at least one selected from the group consisting of SiO₂, HfON, Al₂O₃, TaO₂, TiO₂, and High-k.

6. The semiconductor memory as claimed in claim 2, wherein the dielectric layer is formed of an Si-dot or a nitride layer.

7. The semiconductor memory as claimed in claim 6, wherein the dielectric layer is Si₃N₄.

8. A manufacturing method of a semiconductor memory, comprising:
(a) forming a trench on a first portion of a semiconductor substrate and depositing an insulating material in the trench;
(b) forming a gate stack structure on a second portion of the semiconductor substrate and doping a conductive impurity into the semiconductor substrate adjacent the gate stack structure to form doped regions; and
(c) forming a contact layer on a third portion of the semiconductor substrate adjacent to the trench and on an opposite side of the trench as the gate stack structure.

9. The manufacturing method as claimed in claim 8, wherein forming the trench on the first portion of a semiconductor substrate and depositing the insulating material in the trench comprises:
depositing a nitride layer on the semiconductor substrate;
etching the first portion of the semiconductor substrate to form the trench; and
depositing the insulating layer in the trench and removing the nitride layer.

10. The manufacturing method as claimed in claim 8, wherein forming the gate stack structure on the second portion of the semiconductor substrate and doping the conductive impurity into the semiconductor substrate adjacent the gate stack structure to form doped regions comprises:
depositing layers for forming the gate stack structure on the second portion of the semiconductor substrate and etching the layers to form the gate stack structure; and
forming a first impurity region and a second impurity region using a doping process in which a conductive impurity is doped into the semiconductor substrate adjacent the gate stack structure.

11. The manufacturing method as claimed in claim 10, wherein the first and second impurity regions both have a polarity opposite to that of an upper portion of the semiconductor substrate.

12. The manufacturing method as claimed in claim 10, wherein forming the first and second impurity regions further comprises:
doping a low density impurity into the semiconductor substrate adjacent the gate stack structure;
forming a sidewall spacer on each side of the gate stack structure; and
doping a high density impurity into the semiconductor substrate adjacent the sidewall spacers on the gate stack structure to complete the first and the second impurity regions.

13. The manufacturing method as claimed in claim 10, wherein forming the gate stack structure comprises depositing sequentially an oxide, a dielectric, an oxide, and an electrode material and etching each of the deposited materials.

14. The manufacturing method as claimed in claim 8, wherein forming the contact layer on the third portion of the semiconductor substrate adjacent to the trench and on an opposite side of the trench as the gate stack structure comprises doping a conductive impurity into the semiconductor substrate located at one side of the trench opposite to the gate stack structure.

15. The manufacturing method as claimed in claim 14, wherein the contact layer has a polarity opposite to the first and second impurity regions and has the same polarity as an upper portion of the semiconductor substrate.

16. The manufacturing method as claimed in claim 8, further comprising forming an insulating layer between one of the doped regions and the contact layer.
